(19) United States
(12) Patent Application Publication
(10) Pub. No.: US 2023/0164942 A1
(43) Pub. Date: May 25, 2023

(54) PORTABLE PAPERLESS RECORDER

(71) Applicant: SHENZHEN HUATO SYSTEM CO.,LTD., Bao'an District, (CN)

(72) Inventors: LiXiong Zhang, Bao'an District (CN); MeiWen Chen, Bao'an District (CN)

(21) Appl. No.: 17/649,178

(22) Filed: Jan. 27, 2022

(30) Foreign Application Priority Data
Nov. 23, 2021 (CN) 202111396888.1

(51) Int. Cl. H05K 7/14; H02J 9/06; H02J 7/00; H01R 31/06

(52) U.S. Cl. CPC H05K 7/1427; H02J 9/06; H02J 7/0042; H01R 31/065; G01K 7/021

(57) ABSTRACT

Exemplary embodiments of a portable paperless recorder are disclosed. According to one exemplary embodiment, a portable paperless recorder may include a recorder body, having a signal acquisition board and a main circuit board. The main circuit board is plugged into the signal acquisition board, and comprises a manual reset power loss protection circuit of the microprocessor reset of the paperless recorder. The signal acquisition board comprises an adapter component for connecting the external terminal, and one side of the adapter component comprises a channel cross-connect board for leading through the connection of the external terminal and the adapter components. The channel cross-connect board is engaged with the upper end of the recorder body. In the present disclosure, the signal acquisition board having the adapter component is attachedly connected with the recorder body by screwing. The channel cross-connect board is engaged to the recorder body to further convenience the assembly and disassembly of the signal acquisition board, the channel cross-connect board and the recorder body. When the manufacturers produce paperless recorders with different interfaces, no major changes are required to the paperless recorders for reducing the manufacturing costs.

### CROSS-REFERENCE

The present disclosure claims priority to Chinese application No. 2021113968881 filed 23 Nov., 2021 the entire subject matter and contents of which are incorporated herein by reference.

### FIELD OF THE INVENTION

The present disclosure pertains to a portable paperless recorder and more particular to a portable paperless recorder.

### DESCRIPTION OF RELATED ART

The paperless recorder considers time as a base axis for data collection and calculation, without consuming any commonly used recording facilities. In the process of using the paperless recorder, the details recorded by the recording tools, such as paper, pen, ink are enabled to store in the storage module of the internal instrument, and the stored data of the internal instrument is displayed on the LCD screen after the calculation and simulation.

The present disclosure of paperless recorder is generally connected to the transmitter through external terminal blocks. However, due to the size specification of the external terminal blocks used by the users, the interface terminal of a single specification model is not able to satisfy the needs of different users. In order to meet the needs of different customers, the manufacturers are required to further convenience the replacement of the interfaces of the paperless recorder, thereby adapting the needs of different customers to produce the products with different interfaces, and further reducing the costs of production and development of different interfaces products. Yet, the structure of the paperless recorder in the present disclosure is complicated, and the interface port is inconvenient to be replaced, which allows the manufacturer's production cost and process costing relatively high.

Therefore, the exemplary embodiments of the present disclosure relate to a portable paperless recorder that can, among other things, effectively solve the difficulties when using portable paperless recorders.

### SUMMARY

To attain the advantages and in accordance with the purpose of the present disclosure, as embodied and broadly described herein, one exemplary aspect of the present disclosure may provide a portable paperless recorder comprising: Exemplary embodiments of a portable paperless recorder discloses a portable paperless recorder. According to one exemplary embodiment, a portable paperless recorder may include a recorder body, having a signal acquisition board and a main circuit board. The main circuit board is engaged with the signal acquisition board and comprises a manual reset power loss protection circuit of the microprocessor reset of the paperless recorder. A signal acquisition board comprises an adapter component for connecting the external terminal, and one side of the adapter component comprises a channel cross-connect board for leading the external terminal to connect with the adapter component. The channel cross-connect board is engaged with the upper end of the recorder body.

In one embodiment, the signal acquisition board comprises a universal acquisition board. The adapter components comprise a plurality of plug-type terminal nodes.

In another embodiment, the signal acquisition board is a thermocouple acquisition board; the adapter component includes a thermocouple adapter board and an adapter board is connected to the strip. The adapter board is connected to one end of the strip and is plugged into the thermocouple acquisition board; the adapter board is connected to the other end of the strip and is plugged into the thermocouple adapter board.

In yet another embodiment, the thermocouple adapter board comprises a plurality of arrays of antenna shrapnel is disclosed.

In yet another embodiment, the manual reset power loss protection circuit comprises a reset module, a charge-discharge module, a first power resume module, a second power resume module, and a level lock module. When the reset module is initially activated, the first power resume module is activated, rendering the charge-discharge module to discharge control of the level locking module to lock the output level; when the microprocessor is powered on, the charge-discharge module is compensated for charging by the second power resume module.

In yet another embodiment, the first power resume module comprises a first MOSFET, a first resistor, and a first diode. The gate of the first MOSFET is connected to a reset module, a second power resume module and one end of the first resistor. The source of the first MOSFET is connected to the cathode of the first diode and the other end of the first resistor. The drain of the first MOSFET is connected to the charge-discharge module. The anode of the first diode is connected to the VCC power supply terminal.

In yet another embodiment, the charge-discharge module comprises a capacitor, a second resistor and a second diode. The anode of the second diode is connected to the drain of the first MOSFET, and is also grounded through the capacitor and the second resistor. The cathode of the second diode is connected to the level lock module.

In yet another embodiment, the level lock module comprises a first triode, a third resistor, and a fourth resistor. The base of the first triode is connected to the cathode of the second diode through the third resistor and is grounded through the fourth resistor. The emitter of the first triode is grounded, and the collector of the first triode is connected to the power switch module of the electronic device.

In yet another embodiment, the second power resume module comprises a second triode, a fifth resistor, and a sixth resistor. The base of the second triode is connected to the IO3Pin of the microprocessor through the fifth resistor and is also grounded through the sixth resistor. The emitter of the second triode is grounded, and the collector of the second triode is connected to the gate of the first MOSFET and reset module.

In yet another embodiment, the reset module comprises a reset key, a third diode, a fourth diode, a seventh resistor, and an eighth resistor. One end of the reset key is connected to the cathode of the third diode and the cathode of the fourth diode; the other end of the reset key is grounded and the anode of the third diode is connected to the gate of the first MOSFET and the second triode through a seventh resistor, and the anode of the fourth diode is connected to the reset pin of the microcontroller through the eighth resistor.

Additional objects and advantages of the present disclosure will be set forth in part in the description which follows, and in part will be obvious from the description, or may be learned by practice of the present disclosure. The objects and advantages of the present disclosure will be realized and attained by means of the elements and combinations particularly pointed out in the appended claims.

It is to be understood that both the foregoing general description and the following detailed description are exemplary and explanatory only and are not restrictive of the present disclosure, as claimed.

### BRIEF DESCRIPTION OF THE DRAWING FIGURES

The accompanying drawings, which are incorporated in and constitute a part of this specification, illustrate exemplary embodiments of the present disclosure and together with the description, serve to explain the principles of the present disclosure.

FIG. 1 is an exploded schematic diagram of the paperless recorder with a thermocouple channel in accordance with the teachings of the present disclosure.

FIG. 2 is a schematic diagram of the front housing of the paperless recorder in accordance with the teachings of the present disclosure.

FIG. 3 is a schematic diagram of the end housing of the paperless recorder in accordance with the teachings of the present disclosure.

FIG. 4 is an enlarged view of FIG. 3.

FIG. 5 is a schematic diagram of the thermocouple adapter board in accordance with the teachings of the present disclosure.

FIG. 6 is a schematic diagram of the angle of the thermocouple channel paperless recorder in accordance with the teachings of the present disclosure.

FIG. 7 is a schematic diagram of another angle of the thermocouple channel paperless recorder in accordance with the teachings of the present disclosure.

FIG. 8 is an exploded schematic diagram of the universal channel paperless recorder in accordance with the teachings of the present disclosure.

FIG. 9 is a schematic diagram of the universal acquisition board in accordance with the teachings of the present disclosure.

FIG. 10 is a schematic diagram of the universal channel cross-connect board in accordance with the teachings of the present disclosure.

FIG. 11 is a schematic diagram of the universal channel paperless recorder in accordance with the teachings of the present disclosure.

FIG. 12 is a circuit schematic diagram of the manual reset power loss protection circuit in accordance with the teachings of the present disclosure.

FIG. 13 is a schematic diagram of the three-point cold junction compensation device of the multi-channel thermocouple recorder in accordance with the teachings of the present disclosure.

FIG. 14 is a schematic diagram of the temperature sensor of the three-point cold junction compensation device of the multi-channel thermocouple recorder in accordance with the teachings of the present disclosure.

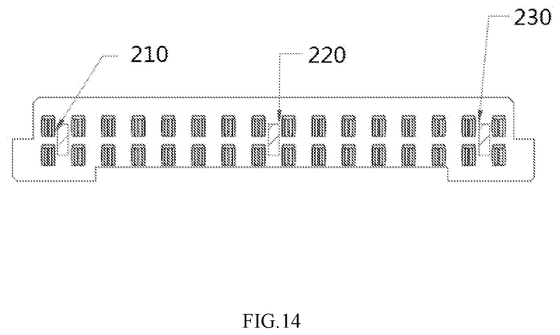

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts.

When a component is indicated as being “installed on,” “attached in,” “engaged with,”or “provided on” another component, it can be directly on the other component or there may be an intervening part at the same time. When a component is indicated as being “connected” or “connected to” another component, it may be directly connected to or connected to another component at the same time.

During the course of the description, the terms left, right, up, and down in the embodiment of the present disclosure only refer to relative concepts or the normal use state of the products, and should not be considered restrictive.

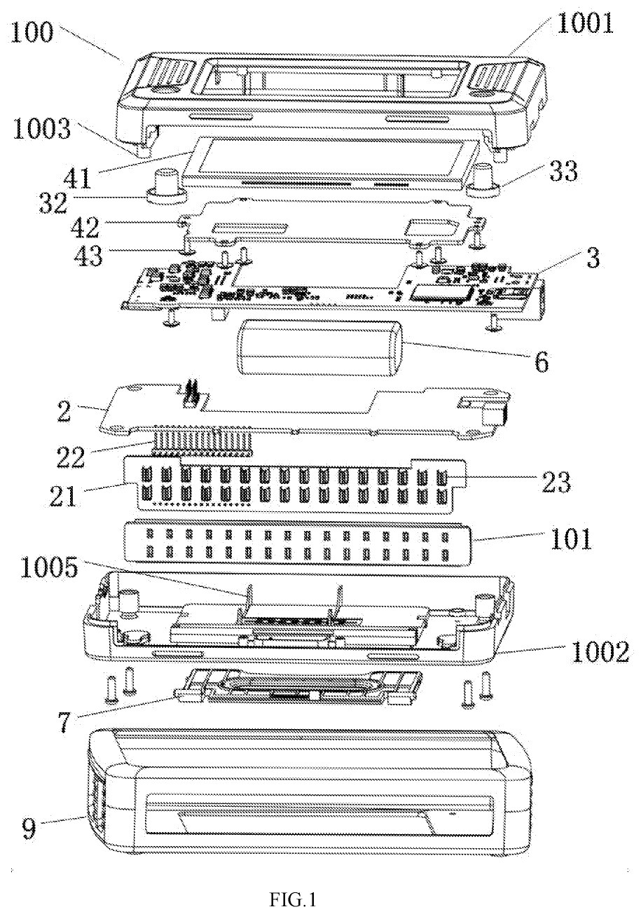

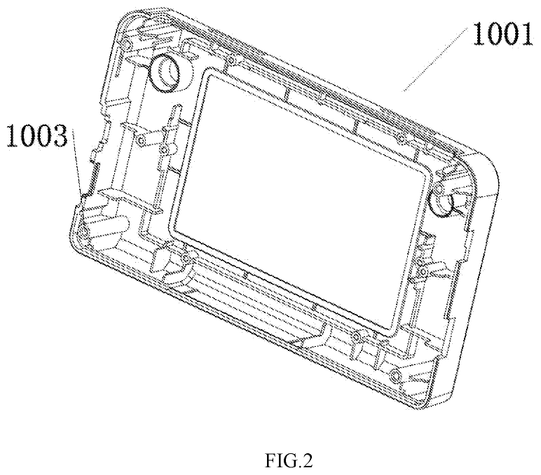

One exemplary embodiment of the present disclosure may provide a portable paperless recorder, as shown in FIG. 1 to FIG. 7, comprising a recorder body 100. The internal of the recorder body 100 is provided with a signal acquisition board and a main circuit board 3. The main circuit board 3 is plugged into the signal acquisition board. The main circuit board 3 comprises a manual reset power loss protection circuit for resetting the microprocessor of the paperless recorder. The signal acquisition board is provided with adapter components for connecting the external terminal, and one side of the adapter components comprise a channel cross-connect board for leading through the connection of the external terminal and the adapter components. The channel cross-connect board is engaged with the upper end of the recorder body 100. In the present disclosure, the signal acquisition board, having the adapter components is attachedly connected with the recorder body 100 by screwing, and is connected with the channel cross-connect board and the recorder body 100 by carding, enabling the assembly and disassembly of the signal acquisition board, the channel cross-connect board and the recorder body 100 to become much easier. When the manufacturers produce the paperless recorders with different interfaces, no major changes are required to the paperless recorders to reduce manufacturing costs.

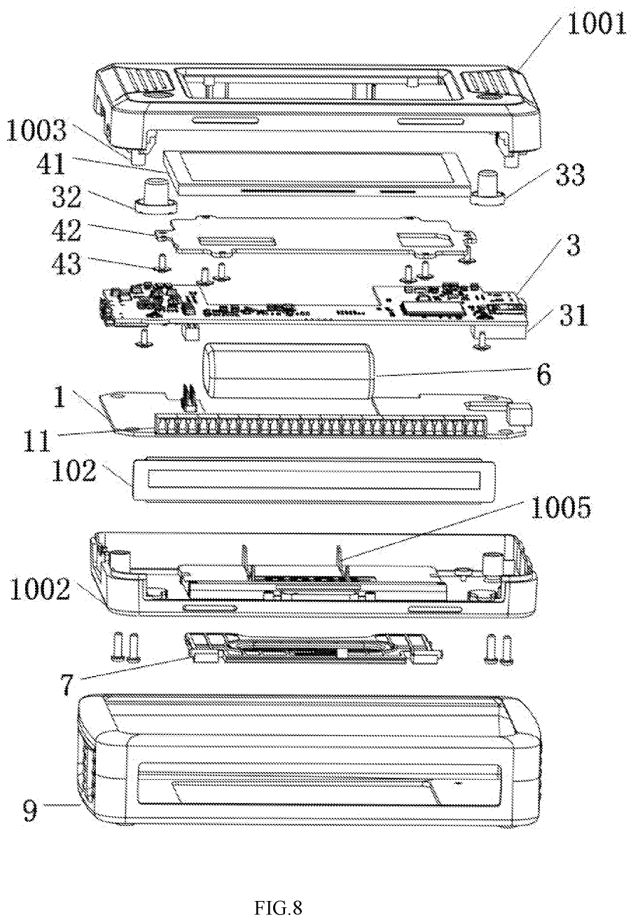

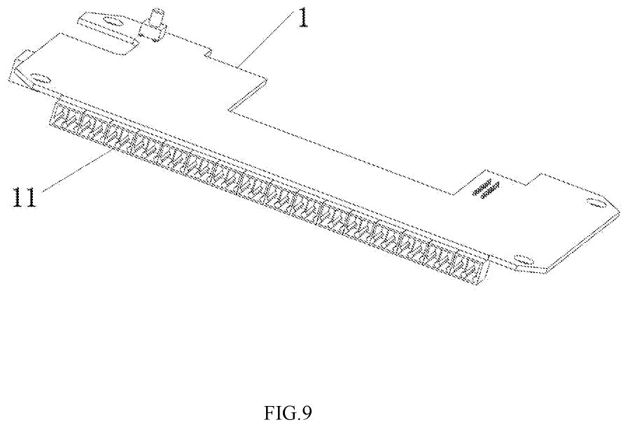

As shown in FIG. 8 to FIG. 10, the signal acquisition board is a universal acquisition board 1. The adapter components comprise a plurality of plug-type terminal nodes 11. The universal acquisition board 1 may collect the current signals, voltage signals, resistance signals, thermocouple signals, etc. of the external input through the plug-type terminal nodes 11. The plug-type terminal nodes 11 are disposed on the upper end of the universal acquisition board 1, and are arranged in consecutive order. The plug-type terminal nodes 11 are disposed on the universal acquisition board 1 by using the securing bolts and glue. In preferred embodiments, the specific number of the plug-type terminal nodes 11 is not restricted, and the number of the plug-type terminal nodes 11 can be 4, 8, 12, 16, etc. In preferred embodiments, the universal acquisition board 1 and the plug-type terminal nodes 11 corresponds to the channel cross-connect board is a universal channel cross-connect board 101. The universal channel cross-connect board 101 is provided with a rectangular notch (not labeled in FIG.), preventing the opening of the plug-type terminal nodes 11 from being shielded; the different numbers of plug-type terminal nodes 11 corresponds to the universal channel cross-connect board 101 with different size of the rectangular notch.

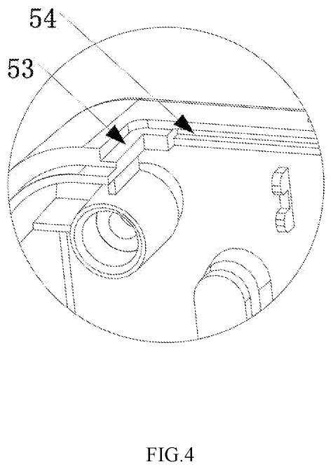

As shown in FIG. 1, FIG. 4, FIG. 8, the signal acquisition board is a thermocouple acquisition board 2. The adapter components comprise a thermocouple adapter board 21 and adaptor board connector strip 22. One end of the adaptor board connector strip 22 is plugged into the thermocouple acquisition board 2; the other end of the adaptor board connector strip 22 is plugged into the thermocouple adapter board 21. In the embodiment of the present disclosure, the thermocouple acquisition board 2 may collect the thermocouple signals of the external input through the thermocouple adapter board 21 and the adaptor board connector strip 22. The difference between the thermocouple signal collected by the universal acquisition board 1 and the plug-type terminal nodes 11, and the thermocouple signal collected by the thermocouple acquisition board 2, the thermocouple adapter board 21 and the adaptor board connector strip 22 is that the size specification of the interfaces for both and the external terminal block is different, through a simple assembly or disassembly of the signal acquisition board and the switching component, to adapt different size specification of the external terminal block by way of substitution/replacement, thereby reducing the manufacturer's production and development costs. As shown in FIG. 1 & FIG. 4, the thermocouple adapter board 21 is vertically disposed on the side of the thermocouple acquisition board 2, and the thermocouple adapter board 21 is attached in the recorder body 100 by a card (not labeled in FIG.). The thermocouple acquisition board 2 and the thermocouple adapter board 21 comprise a jack used for plugging into the adaptor board connector strip 22. The adaptor board connector strip 22 comprises a plurality of L-shaped pins (not labeled in FIG.). The upper end of the L-shaped pin is plugged into the jack on the thermocouple acquisition board 2, and the lower end of the L-shaped pin is plugged into the thermocouple adapter board 21 and is connected to the thermocouple acquisition board 2 and the thermocouple adapter board 21 through the L-shaped pin. On the one hand, the plugging is much easier to assemble and disassemble compared to the cable connection; on the other hand, the plugging prevents the chaos in circuit connection caused by multiple internal cables of the paperless recorder.

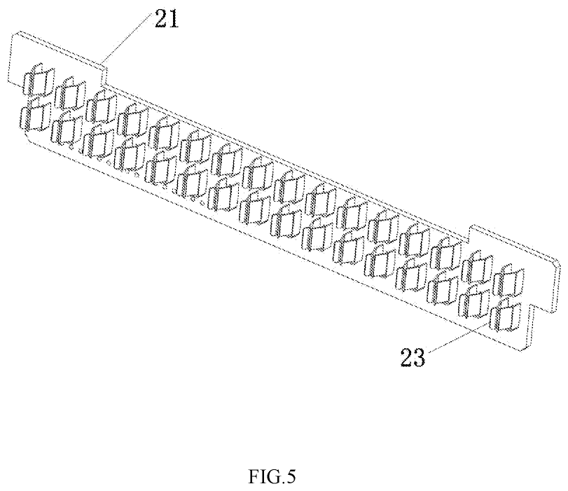

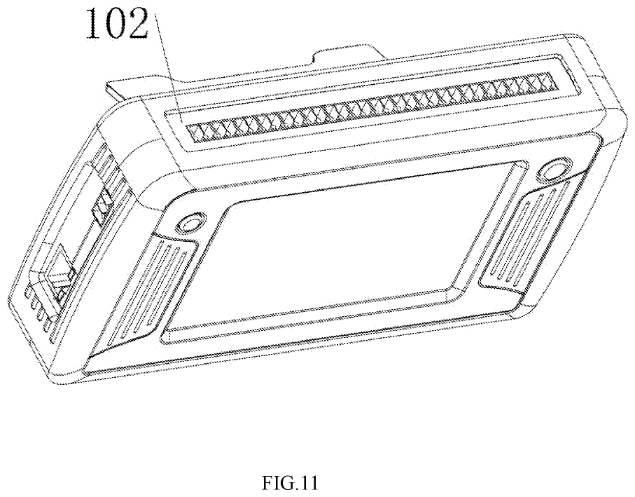

As shown in FIG. 1, FIG. 5, FIG. 11, the thermocouple adapter board 21 comprises a plurality of arrays of antenna shrapnel 23 is disclosed. The number of the L-shaped pin corresponds to the number of the jack, and the number of the L-shaped pins is greater than or equal to the number of the antenna shrapnel 23. In preferred embodiments, the specific number of antenna shrapnel 2 is not restricted, and the number of antenna shrapnel 23 can be 4, 8, 12, 16, etc. In preferred embodiments, the thermocouple acquisition board 2, the thermocouple adapter board 21, the adaptor board connector strip 22, and the antenna shrapnel 23 corresponding to the channel cross-connect board is the thermocouple channel cross-connect board 102. The thermocouple channel cross-connect board 102 is provided with the opening corresponding to the number of antenna shrapnel 23.

As also shown in FIG. 1 to FIG. 3, the recorder body 100 comprises a front housing 1001 and an end housing 1002. The front housing 1001 is provided with pegs 1003. The end housing 1002 is provided with a counterbore (not labeled in FIG.). The bolts are sequentially attached to the front housing 1001 and the end housing 1002 with counterbore and the pegs 1003 to simplify the assembly or disassembly, and the counterbore settings prevent the protruded surface of the recorder body 100 after the bolt is tightened and enhance the appearance of the product. The signal acquisition board is disposed on the front housing 1001 and the end housing 1002 by screwing. The card is disposed on the end housing 1002, and the number of the card is at least two. In preferred embodiments, there are 4 cards, the assembly of the thermocouple adapter board 21 is further stabilized by all 4 cards, and preventing the inconvenience of plugging caused by the movement of the thermocouple adapter board 21 when the user plugging the exterior joint. The card is a board-shaped card fittings in FIG. 4. The card is provided with a card slot (not labeled in FIG.). The thermocouple adapter board 21 is plugged into the slot of the card, and the thermocouple adapter board 21 is engaged with to the end housing 1002 through the card slot. The width of the card slot is equal to or slightly smaller than the thickness of the thermocouple adapter board 21, and the thermocouple adapter board 21 is attached by engaging, on the one hand, the way of securing/fixing is simpler than to secure with bolts; on the other hand, preventing the poor fixation and instability issue after securing caused by the arrangement direction of the thermocouple adapter board 21. The front housing 1001 and the end housing 1002 are attached by screwing, thereby facilitating the assembly or disassembly of the recorder body 100 and further simplifying the replacement of the signal acquisition board, the adapter components and the channel cross-connect board.

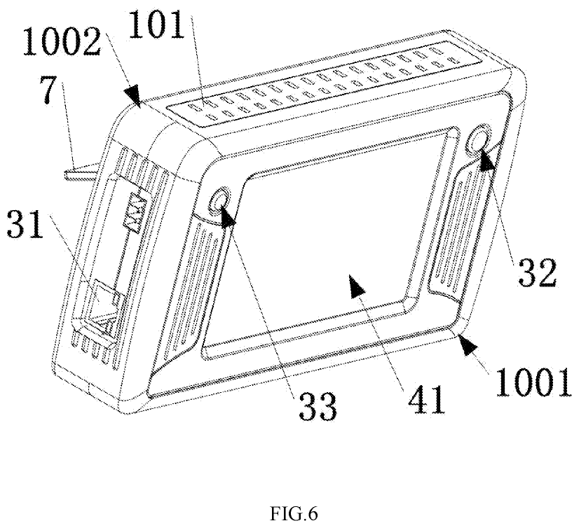

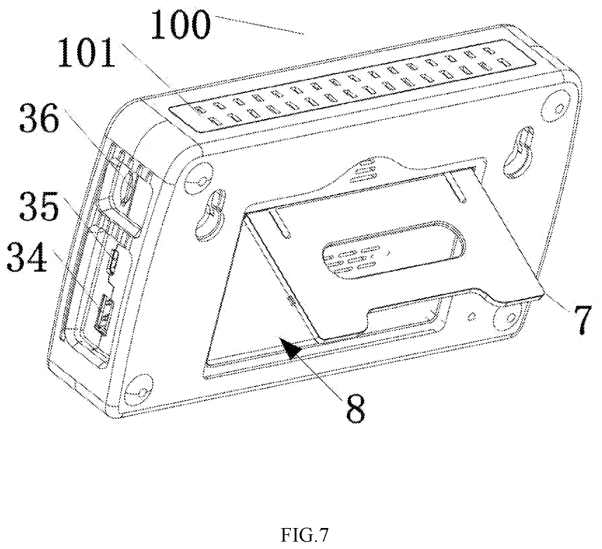

As shown in FIG. 1, FIG. 6, FIG. 7 and FIG. 8, the internal of recorder body 100 is further comprised with a main circuit board 3. The main circuit board 3 is provided with one side of the front housing 1001 by screwing, and the main circuit board 3 is further provided with an RJ45 interface module 31, a HOME key module 32, a switch-key module 33, a USB interface module 34, a Type-C interface module 35, and an SD card module 36. The main circuit board 3 is connected to the display screen 41 and is further plugged into the signal acquisition board. The main circuit board 3 is further provided with a microprocessor, a power switch module and a manual reset power loss protection circuit.

A display screen 41 and a display screen with press panel 42 are sequentially provided between the front housing 1001 and the main circuit board 3. The display screen 41 is bolted securing through the front housing 1001 and the display screen with press panel 42. The press panel bolt 43 is attached to the display screen 41 to the front housing 1001 through an ear-shaped fixator on the display screen with press panel 42. The front housing 1001 is further provided with a stopper for restricting the movement of the display screen 41. The position of the display screen 41 is restricted from all sides by the stoppers.

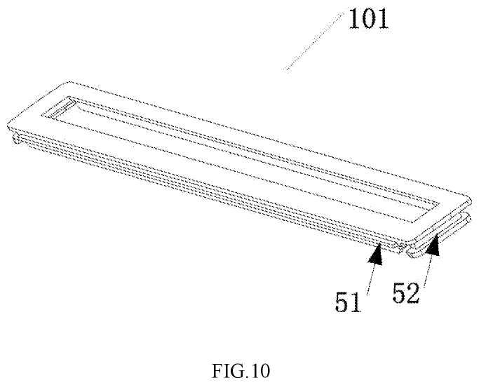

As shown in FIG. 4, FIG. 8, FIG. 10, one pair side of channel cross-connect board is provided with the first extension 51. Another pair side of channel cross-connect board is provided with the first card fittings slot 52. Both the front housing 1001 and the end housing 1002 are provided with a second card fittings slot 54 and a second extension 53 corresponding to the first extension 51 and the first card fittings slot 52. The channel cross-connect board is engaged with the front housing 1001 and the end housing 1002. When disassembling the channel cross-connect board, the bolts connecting to the front housing 1001 and the end housing 1002 shall be firstly removed, and then disassembling the end housing 1002 and the front housing 1001. Twitching the channel cross-connect board allows the first extension 51 to move to one side along the second card fittings slot 54, and can immediately remove the channel cross-connect board.

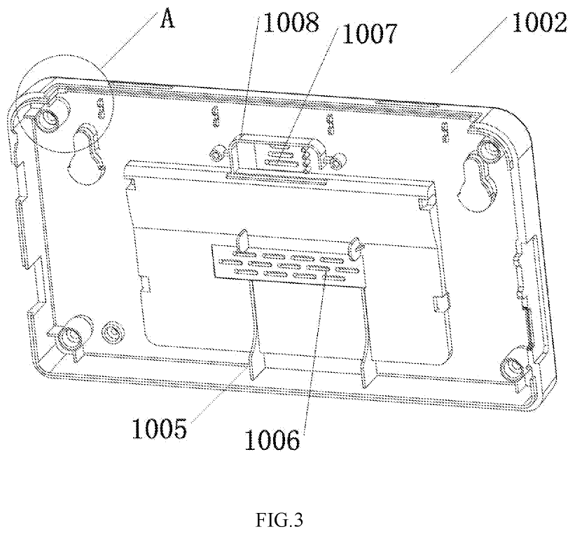

As also shown in FIG. 1, FIG. 3, FIG. 8, the recorder body 100 is further comprised with a battery 6. Battery 6 is connected to the main circuit board 3 through a wire. Battery 6 is engaged with stopper 1005 of the end housing 1002, and the battery 6 is further glued on the display screen with press panel 42 by protective elastic foam with double-sided adhesive. The back of the recorder body 100 is provided with a bracket 7 for supporting the recorder, the bracket 7 is hinged to the end housing 1002, and the back of the end housing 1002 is provided with a storage slot 8 for storing the bracket 7. The end housing 1002 of the paperless recorder is further provided with battery heat dissipation holes 1006 and sensor vents 1007. The battery heat dissipation holes 1006 and sensor vents 1007 are provided with a single-sided adhesive dustproof net. The side of the sensor vent 1007 is provided with a sensor placement 1008 for assembling the sensor. The sensor is attached in the sensor placement 1008 through a lid (not labeled in FIG.), and the lid is attached to a bolt seat (not labeled in FIG.) on the side of the sensor placement by bolts. The setting of bracket 7 enables the recorder to be supported during use, and thereby facilitating the observation of the data on the display screen 41. The outer side of the recorder body 100 is shielded with a protective case 9 for protecting the recorder body 100, and the protective case 9 is made of silica gel or thermoplastic polyurethane elastomer rubber.

In order to ensure the paperless recorder can be manually restarted the system and to improve the shortcomings of the existing reset circuit when the system is abnormal and if necessary, the present disclosure is based on the MOSFET switch by leading a capacitor storage circuit and a switch circuit, and utilizing the charge and discharge characterization of the capacitor to solve the manual reset and to solve the problem of power loss of the manual reset circuit under the soft-switching state.

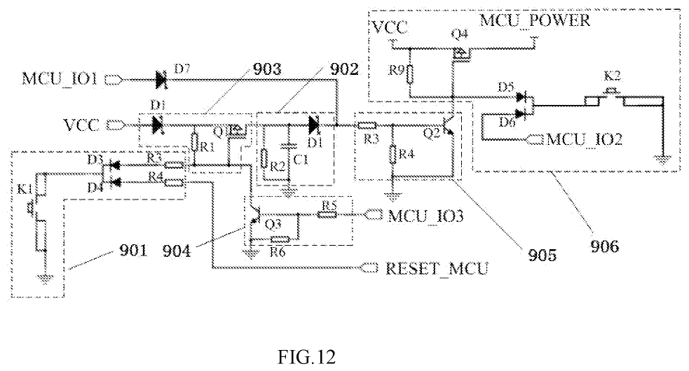

The present disclosure is further provided with a manual reset power loss protection circuit for resetting the microprocessor of the paperless recorder. As shown in FIG. 12, the manual reset power loss protection circuit includes a reset module 901, a charge-discharge module 902, a first power resume module 903, a second power resume module 904 and a level lock module 905. The reset module 901 and the second power resume module 904 are connected to the first power resume module 903. The first power resume module 903 is connected to the IO1 pin of the microprocessor and the level lock module 905.

When the resetting of the reset module 901 is activated, the first power resume module 903 is started to allow the charge-discharge module 902 discharge control the level locking module 905 to lock the output level; when the microprocessor is powered on, the charge-discharge module 902 is compensated and is charged by the second power resume module 904 for compensating the insufficient charging of the capacitor C1 of the charge-discharge module 902 during the manual reset, effectively preventing power loss during the reset, thereby improving the reliability of reset.

As shown in FIG. 12, the first power resume module 903 comprises a first MOSFET Q1, a first resistor R1, and a first diode D1. The first MOSFET Q1 is a P-channel MOSFET. When the MOSFET Q1 is conducted, the first resistor R1 is a pull-up resistor, and the first diode D1 is mainly used for the isolation preventing the signal reverse.

The gate of the first MOSFET Q1 is connected to the reset module 901, the second power resume module 904 and one end of the first resistor R1. The source of the first MOSFET Q1 is connected to the cathode of the first diode D1 and the other end of the first resistor R1. The drain of the first MOSFET Q1 is connected to the charge-discharge module 902. The anode of the first diode D1 is connected to the VCC power supply terminal.

The charge-discharge module 902 comprises a capacitor C1, a second resistor R2, and a second diode D2. The capacitor C1 is used for storage and power supply. The second diode D2 is further used for isolation, preventing the signal reverse.

In an embodiment of the present disclosure, the anode of the second diode D2 is connected to the drain of the first MOSFET Q1 and is grounded through the capacitor C1, and the second resistor R2. The cathode of the second diode D2 is connected to the level lock module 905.

The level lock module 905 comprises a first triode Q2, a third resistor R3, and a fourth resistor R4. The first triode Q2 is an NPN transistor. The first triode Q2 is conducted when its base is high level. The third resistor R3 is a current-limiting resistor.

The base of the first triode Q2 is connected to the cathode of the second diode D2 through a third resistor R3, and is further grounded through a fourth resistor R4. The emitter of the first triode Q2 is grounded, and the collector of the first triode Q2 is connected to the power switch module of the paperless recorder.

As shown in FIG. 12, the second power resume module 904 comprises a second triode Q3, a fifth resistor R5, and a sixth resistor R6. The second triode Q3 is also an NPN transistor. The fifth resistor R5 is also a current-limiting resistor when its base is high level.

The base of the second triode Q3 is connected to the IO3 pin of the microprocessor through the fifth resistor R5 and is also grounded through the sixth resistor R6. The emitter of the second triode Q3 is grounded, and the collector of the second triode Q3 is connected to the gate of the first MOSFET Q1 and reset module 901. After the microprocessor is powered on, its IO3 pin outputs high level rendering the conduction of the second triode for compensating the charging time of the capacitor C1.

The reset module 901 comprises a reset key K1, a third diode Q3, a fourth diode D4, a seventh resistor R7, and an eighth resistor R8. The reset key K1 is a switch button for the user to manually start the power. One end of the reset key K1 is connected to the cathode of the third diode Q3 and the cathode of the fourth diode D4; the other end of the reset key K1 is grounded, and the anode of the third diode Q3 is connected to the gate of the first MOSFET Q1 through a seventh resistor R7, and the second triode Q3 of the collector and the anode of the fourth diode D4 IS connected to the reset pin of the microcontroller through the eighth resistor R8.

The power switch module 906 comprises a power key K2, a second MOSFET Q4, a fifth diode D5, a sixth diode D6, and a ninth resistor R9. The power key K2 can further adopt a switch button for the user to manually start the power. The second MOSFET Q4 is further used as a P-channel MOSFET, and when the gate is low level, the second MOSFET Q4 is conducted. The ninth resistor R9 is a pull-up resistor.

One end of the power key K2 is connected to the cathode of the fifth diode D5 and the cathode of the sixth diode D6; the anode of the sixth diode D6 is connected to the IO2 pin of the microprocessor; the anode of the fifth diode D5 is connected to the gate of the second MOSFET Q4 and the collector of the first triode, and is further connected to the VCC power supply terminal through the ninth resistor R9.

The manual reset power loss protection circuit further comprises a seventh diode D7. The seventh diode D7 is an isolation diode. The anode of the seventh diode D7 is connected to the IO1 pin of the microprocessor. The cathode of the seventh diode D7 is connected to the cathode of the second diode D2 and is further connected to the base of the second triode Q3 through the third resistor R3.

In order to have a better understanding of the present invention, the working principle of the manual reset power loss protection circuit of the present invention is shown in the details of the combined FIG. 12:

Considering the temperature and humidity recorder as an example, as shown in FIG. 12, the VCC power supply terminal is the power supply system. The microprocessor can adopt MSP430 series chips, such as the MSP430F6736 chip. The chip has rich IO (such as the P port of the MSP430 chip) and has a good expansion performance, such as IO3 port.

When the reset key is pressed, the reset pin of the microprocessor RESET_MCU changes to low level, triggering the reset of the microprocessor. At the same time, the first MOSFET Q1, the first triode Q2, and the second MOSFET Q4 are all conducted. During the reset, the capacitor C1 is discharged sustaining the conduction of the first triode Q2, and the level of the IO1 port of the microprocessor is locked to sustain the power supply system, avoiding the power loss of the system. The charge stored in the capacitor C1 comes from the conduction of the first MOSFET Q1 when the reset key K1 is pressed. In the meanwhile, the VCC power supply system of the capacitor C1 is charged through the first diode D1.

In addition, when the reset key is pressed, the charge provided by the capacitor C1 is not sufficient to sustain the power consumed by the conduction of the first transistor Q2 during the reset. Therefore, in the present disclosure, when the microprocessor is powered on, the IO3 port outputs high level to control the conduction of the second MOSFET Q4 and further enables the first MOSFET Q1 to provide it with a charging time of 500 mS to compensate for the insufficient charging of the capacitor C1 when the reset key is pressed.

In addition to that, the existing paperless recorders face multi-channel thermocouple collection, and the common cold-junction compensation method has poor accuracy and consistency in achieving multi-channel. With the increasing demand for multi-channel acquisition instruments in the industrial field, the common methods are unable to meet the requirements of high precision and reliability of cold junction compensation. Based on this, the present disclosure is also provided with a three-point cold junction compensation device, for the purpose of solving the problem of insufficient accuracy of multi-channel acquisition and compensation in the present disclosure.

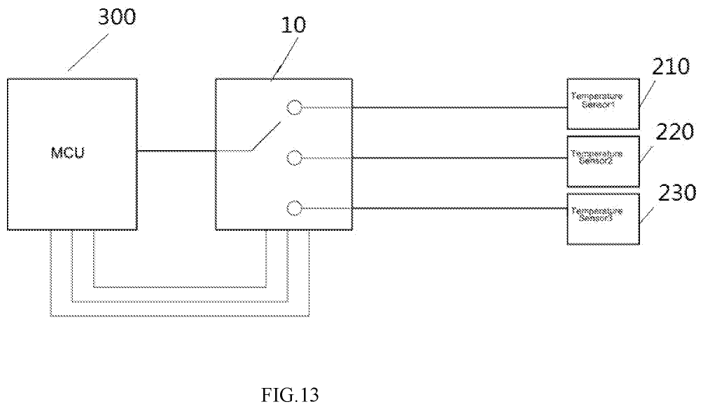

As shown in FIGS. 13 & 14, the three-point cold junction compensation device comprising: an analog switch 10 and a temperature sensor. The temperature sensor further comprising: a first temperature sensor 210, a second temperature sensor 220, and a third temperature sensor 230 (corresponding to Temperature Sensor 1, Temperature Sensor 2 and Temperature Sensor 3). The first temperature sensor 210, the second temperature sensor 220, and the third temperature sensor 230 are respectively connected to the analog switch 10 through a communication bus. The present disclosure reads the data of each temperature sensor through the switching sequence of the analog switch 10. Since the temperature of each channel of the multi-channel thermocouple recorder is affected by the environment, there will be a gradient difference. The cold junction temperature of each channel can be obtained by averaging the difference between the data read by the three temperature sensors to each channel. Compared to the conventional multi-channel cold junction compensation equipped with multiple temperature probes, this preferred embodiment uses fewer materials, is low cost, and has good reliability.

In an embodiment of the present disclosure, the first temperature sensor 210, the second temperature sensor 220, and the third temperature sensor 230 adopt three digital temperature sensors of the same model for digital temperature collection, such as ds18b20 temperature sensor. The analog switch 10 adopts RS2255XN and is mainly used to switch various temperature sensor bus channels. The three-point cold junction compensation device of the multi-channel thermocouple recorder further comprises a control chip 300. The control chip 300 is connected to the analog switch 10 to output a control signal, and the first temperature sensor 210, the second temperature sensor 220, and the third temperature sensor 230 are sequentially selected by the analog switch 10. A shared communication bus is used to read the data of each temperature sensor in sequence.

In an embodiment of the present disclosure, the multi-channel acquisition instrument has 16 channels. The first temperature sensor 210 and the third temperature sensor 230 are respectively located on both sides of the channel of the multi-channel acquisition instrument. The second temperature sensor 220 is located between the eighth channel and the ninth channel of the multi-channel acquisition instrument. The first temperature sensor 210, the second temperature sensor 220 and the third temperature sensor 230 share a single-bus communication; the bus selection is switched through a four-channel analog switch (analog switch 10); the control chip 300 (MCU) outputs control signals, the first temperature sensor 210, the second temperature sensor 220 and the third temperature sensor 230 (a shared communication bus is used) are sequentially selected, and the data of each temperature sensor are sequentially read. As the temperature of each channel of the multi-channel acquisition instrument is affected by the environment will show a gradient difference, the cold junction temperature of each channel can be obtained based on averaging the difference between the data read by the three temperature sensors to each channel. Compared with the traditional cold junction compensation for each channel, the temperature sensor is placed separately to save the cost of the temperature sensor, reduce the difficulty of PCB board design, and achieve higher cost-effective cold junction temperature compensation.

In summary, the present disclosure of a portable paperless recorder, comprising a recorder body, having a signal acquisition board and a main circuit board. The main circuit board is plugged into the signal acquisition board, and comprises a manual reset power loss protection circuit of the microprocessor reset of the paperless recorder. The signal acquisition board comprises an adapter components for connecting the external terminal, and one side of the adapter components comprises a channel cross-connect board for leading through the connection of the external terminal and the adapter components. The channel cross-connect board is engaged with the upper end of the recorder body. In the present disclosure, the signal acquisition board having the adapter component is attachedly connected with the recorder body by screwing. The channel cross-connect board is engaged to the recorder body to further convenience the assembly and disassembly of the signal acquisition board, the channel cross-connect board and the recorder body. When the manufacturers produce the paperless recorders with different interfaces, no major changes are required to the paperless recorders for reducing the manufacturing costs. When the reset module has manually started the reset, the first power resume module is started rendering the charge-discharge module to discharge control of the level locking module to lock the output level; when the microprocessor is powered on, the charge-discharge module is compensated and charged by the second power resume module for compensating the insufficient charging of the capacitor of the charge-discharge module during the manual reset, which effectively preventing power failure during the reset, thereby improving the reliability of reset.

The above-described exemplary embodiments are intended to be illustrative in all respects, rather than restrictive, of the present invention. Thus the present invention is capable of many variations in detailed implementation that can be derived from the description contained herein by a person skilled in the art. All such variations and modifications are considered to be within the scope and spirit of the present invention as defined by the following claims.

What is claimed is:

1. A portable paperless recorder, comprising a recorder body having a signal acquisition board and a main circuit board. The main circuit board is engaged with the signal acquisition board, and is comprised with a manual reset power loss protection circuit of the microprocessor reset of the paperless recorder. The signal acquisition board comprises an adapter component for connecting external terminal, and one side of the adapter components comprises a channel cross-connect board for leading through the connection of the external terminal and the adapter components. The channel cross-connect board engaged with the upper end of the recorder body.

2. The portable paperless recorder of claim 1, wherein the signal acquisition board comprises a universal acquisition board. The adapter components comprise a plurality of plug-type terminal nodes.

3. The portable paperless recorder of claim 1, wherein the signal acquisition board is a thermocouple acquisition board. The adapter component comprises a thermocouple adapter board and an adapter board connector strip. One end of the adapter board connector strip is plugged into the thermocouple acquisition board; the other end of the adapter board connector strip is plugged into the thermocouple adapter board.

4. The portable paperless recorder of claim 3, wherein the thermocouple adapter board comprises a plurality of arrays of antenna shrapnel is disclosed.

5. The portable paperless recorder of claim 1, wherein the manual reset power loss protection circuit comprises a reset module, a charge-discharge module, a first power resume module, a second power resume module, and a level lock module. When the reset module is started, the first power resume module is started to allow the charge-discharge module to discharge control of the level locking module to lock the output level; when the microprocessor is powered on, the charge-discharge module is compensated for charging by the second power resume module.

6. The portable paperless recorder of claim 5, wherein the first power resume module comprises a first MOSFET, a first resistor, and a first diode. The gate of the first MOSFET is connected to the reset module, the second power resume module and one end of the first resistor. The source of the first MOSFET is connected to the cathode of the first diode and the other end of the first resistor. The drain of the first MOSFET is connected to the charge-discharge module. The anode of the first diode is connected to the VCC power supply terminal.

7. The portable paperless recorder of claim 6, wherein the charge-discharge module comprises a capacitor, a second resistor and a second diode. The anode of the second diode is connected to the drain of the first MOSFET, and is grounded through the capacitor and the second resistor. The cathode of the second diode is connected to the level lock module.

8. The portable paperless recorder of claim 7, wherein the level lock module comprises a first triode, a third resistor, and a fourth resistor. The base of the first triode is connected to the cathode of the second diode through the third resistor and is grounded through the fourth resistor. The emitter of the first triode is grounded, and the collector of the first triode is connected to the power switch module of the electronic device.

9. The portable paperless recorder of claim 7, wherein the second power resume module comprises a second triode, a fifth resistor, and a sixth resistor. The base of the second triode is connected to the IO3Pin of the microprocessor through the fifth resistor and is grounded through the sixth resistor. The emitter of the second triode is grounded, and the collector of the second triode is connected to the gate of the first MOSFET and reset module.

10. The portable paperless recorder of claim 9, wherein the reset module comprises a reset key, a third diode, a fourth diode, a seventh resistor, and an eighth resistor. One end of the reset key is connected to the cathode of the third diode and the cathode of the fourth diode; the other end of the reset key is grounded, and the anode of the third diode is connected to the gate of the first MOSFET through a seventh resistor, and the second triode of the collector and the anode of the fourth diode are connected to the reset pin of the microcontroller through the eighth resistor.
